(19) United States
(12) Patent Application Publication
(10) Pub. No.: US 2011/0248283 A1
(43) Pub. Date: Oct. 13, 2011

(54) VIA STRUCTURE OF A SEMICONDUCTOR DEVICE AND METHOD FOR FABRICATING THE SAME

(76) Inventors: Jianjun Cao, Torrance, CA (US); Robert Beach, La Crescenta, CA (US); Alexander Lidow, Marina Del Ray, CA (US); Alana Nakata, Redondo Beach, CA (US)

(21) Appl. No.: 13/081,140

(22) Filed: Apr. 6, 2011

Related U.S. Application Data
(60) Provisional application No. 61/321,784, filed on Apr. 7, 2010.

(51) Int. Cl. H01L 29/20; H01L 21/28

(52) U.S. Cl. 257/76; 438/586; 257/E29.089; 257/E21.158

(57) ABSTRACT

Semiconductor devices, such as GaN HEMT and HFET devices, and methods of forming such devices, with a via that provides an electrical connection between a contact and a corresponding external contact pad. Embodiments include semiconductor devices with a via extending through a dielectric material to connect a gate to a corresponding external contact pad, and semiconductor devices with a via extending through a dielectric material to connect an Ohmic contact and a corresponding external contact pad. Embodiments also include semiconductor devices with a via connecting an external contact pad to a gate that is formed above a dielectric material.

### CROSS-REFERENCE TO RELATED APPLICATION

This application claims priority to U.S. Provisional Patent Application No. 61/321,784, filed Apr. 7, 2010 and entitled VIA STRUCTURE OF A GaN HEMT DEVICE AND METHOD FOR FABRICATING THE SAME, which is hereby incorporated by reference in its entirety.

### FIELD OF THE INVENTION

The present invention relates to the field of semiconductor devices, and particularly to the manufacture and interconnection of elements in gallium nitride (GaN) high electron mobility transistor (HEMT), heterojunction field effect transistor (HFET), and/or modulation doped field effect transistor (MODFET) semiconductor devices.

### BACKGROUND OF THE INVENTION

Gallium nitride (GaN) semiconductor devices are increasingly desirable because of their ability to switch at high frequency, to carry large current, and to support high voltages. Development of GaN semiconductor devices has generally been aimed at high power/high frequency applications. Devices fabricated for these types of applications are based on general device structures that exhibit high electron mobility and are referred to variously as heterojunction field effect transistors (HFET), high electron mobility transistors (HEMT), or modulation doped field effect transistors (MODFET). These types of devices can typically withstand high voltages, e.g., 30V-to-2000 Volts, while operating at high frequencies, e.g., 100 kHZ-100 GHz.

A GaN HEMT device includes a nitride semiconductor with at least two nitride layers. Different materials formed on the semiconductor or on a buffer layer causes the layers to have different band gaps. The different material in the adjacent nitride layers also causes polarization, which contributes to a conductive two dimensional electron gas (2DEG) region near the junction of the two layers, specifically in the layer with the narrower band gap.

The nitride layers that cause polarization typically include a barrier layer of AlGaN adjacent to a layer of GaN to include the 2DEG, which allows charge to flow through the device. This barrier layer may be doped or undoped. Because the 2DEG region exists under the gate at zero gate bias, most nitride devices are normally on, or depletion mode devices. If the 2DEG region is depleted, i.e. removed, below the gate at zero applied gate bias, the device can be an enhancement mode device. Enhancement mode devices are normally off and are desirable because of the added safety they provide and because they are easier to control with simple, low cost drive circuits. An enhancement mode device requires a positive bias applied at the gate in order to conduct current.

GaN transistors are lateral devices. Gate contact, source contact, and drain contact are typically on the front side of the die. The gate is located between the source and drain. At the device unit cell level, separation between drain and source is small, e.g., 1 um to 30 um. In addition, the dimensions of the gate, drain, and source elements themselves are even smaller. Such dimensions are too small for the Ohmic gate, drain, and source elements to connect directly to the external terminals. Instead, large pads electrically connected to the Ohmic gate, drain, and source connections are typically used. Such pads are typically 300 um or bigger. In order to arrange and connect these large pads in an efficient manner, a three-dimensional network of multi-level metals and via structures is used.

FIG. 8 illustrates a cross-sectional view of a GaN HEMT device 1 with a conventional metal and via structure for interconnecting drain, source, and gate external contact pads with corresponding Ohmic contacts.

Device 1 includes an epitaxial structure of conventional GaN semiconductor materials including a substrate 11, transition layers 12, buffer material 13, and barrier material 14. Device 1 also includes a gate composed of gate metal 816 on gate material 815. Gate material 815 preferably has a thickness in the range of about 100 Å to about 2000 Å. Additionally, gate material 815 is preferably composed of a p-type GaN material having a doping concentration in the range of about 10¹⁸ to about 10²¹ atoms per cm³. Gate metal 816 can be epitaxially grown on the semiconductor materials, or alternatively can be deposited on top of gate material 815. Gate metal 816 can be made of a refractory metal or its compound, e.g., tantalum (Ta), tantalum nitride (TaN), titanium nitride (TiN), palladium (Pd), tungsten (W), tungsten silicide (WSi₂), and preferably has a thickness in the range of about 0.05 um to 1 um.

Device 1 also includes a dielectric material 817 formed over a portion of barrier material 14. Dielectric material 817 is typically formed as a layer that covers gate metal 816 as well as the exposed portions of barrier material 14. During the manufacturing process of conventional device 1, however, the portion of dielectric material 817 above the gate metal 816 is typically removed, along with portions of dielectric material 817 that are removed to form openings for source and drain contacts 818, 819.

In conventional device 1, source, drain, and gate contacts 818, 819, 830 are formed from Ohmic contact metals using a contact mask and etch process. The Ohmic contact metal is typically composed primarily of an Aluminum (Al) material. A second dielectric material 820 is then deposited over source, drain, and gate Ohmic contact metals 818, 819, 830, and source, gate, and drain vias 821, 822, 823 are formed and traverse dielectric material 820 and provide electrical connections to source, gate, and drain Ohmic contact metals 818, 830, 819, respectively.

During the formation of device 1, a rapid thermal anneal (RTA) process is used to establish Ohmic contact between the 2DEG located beneath barrier layer 14 and source and drain Ohmic contacts 818, 819. Because known RTA processes typically include temperatures in a range of about 800° C. to 900° C., the aluminum in the gate Ohmic contact metal 830 can melt during the RTA process. This can result in a reaction taking place between the aluminum from gate Ohmic contact metal 30, the refractory metal of gate metal 816, and/or the p-type GaN material of gate material 815. This reaction, which is at least partially due to Ohmic contact metal 30 being mainly composed of aluminum, can lead to gate degradation in device 1.

FIG. 9 illustrates a cross-sectional view of another GaN HEMT device 2. Device 2 includes similar features as device 1 (FIG. 8), and like reference numbers indicate like features unless otherwise noted. Device 2 presents one way that could be considered for addressing the gate degradation issue discussed above in connection with FIG. 8. Device 2 includes a contact metal 931 above the gate that is composed of a type of metal other than Ohmic contact metal used in source and drain Ohmic contacts 818, 819.

While the use of a metal other than Ohmic contact metal above gate metal 816 in device 2 may limit the problem of gate degradation discussed above with regard to device 1 (FIG. 8), the formation of a different type of metal increases the number of manufacturing process steps for device 2. For example, the manufacturing process for device 2 would typically require at least two more photo mask processes than the manufacturing process for device 1. First, after performing an RTA process to establish Ohmic contacts between the 2DEG and source and drain contacts 818, 819, an additional mask would be used to etch off the portion of dielectric material 817 above gate metal 816. Second, another additional mask would be used to form metal 931 (such as through a lift-off process).

Accordingly, it is desirable to provide a semiconductor device with a via structure that enables small unit cell dimensions and large pads on the top level. It is also desirable to provide a semiconductor device including such a via structure that has a reduced risk of gate degradation and that does not require a significant increase in the number of steps in the manufacturing process. It would also be desirable to provide an efficient process for manufacturing such a GaN device.

### SUMMARY OF THE INVENTION

The present invention achieves the foregoing objectives by providing semiconductor devices, such as GaN HEMT and HFET semiconductor devices, that include a via that provides an electrical connection between a contact and a corresponding external contact pad. Embodiments include semiconductor devices with a via extending through a dielectric material to connect a gate to a corresponding external contact pad, and semiconductor devices with a via extending through a dielectric material to connect an Ohmic contact and a corresponding external contact pad. Embodiments also include semiconductor devices with a via connecting an external contact pad to a gate that is formed above a dielectric material. The invention also includes methods for forming such semiconductor devices.

### BRIEF DESCRIPTION OF THE DRAWINGS

FIG. 1 illustrates a cross-sectional view of a semiconductor device according to an embodiment described herein.

FIGS. 2A-2G illustrate the formation of a semiconductor device according to an embodiment described herein.

FIGS. 3A-3F illustrate the relative locations of gate, drain Ohmic contact, source Ohmic contact, Ohmic contact metal, via, and an upper level metal of a semiconductor device according to an embodiment described herein.

FIG. 4 illustrates a cross-sectional view of a semiconductor device according to another embodiment described herein.

FIGS. 5A-5G illustrate the formation of a semiconductor device according to an embodiment described herein.

FIG. 6 illustrates a cross-sectional view of a semiconductor device according to another embodiment described herein.

FIG. 7 illustrates a cross-sectional view of a semiconductor device according to another embodiment described herein.

FIG. 8 illustrates a cross-sectional view of a GaN semiconductor device with a conventional via structure.

FIG. 9 illustrates a cross-sectional view of another GaN semiconductor device with a conventional via structure.

### DETAILED DESCRIPTION OF THE PREFERRED EMBODIMENTS

In the following detailed description, reference is made to certain embodiments. These embodiments are described with sufficient detail to enable those skilled in the art to practice them. It is to be understood that other embodiments may be employed and that various structural, logical, and electrical changes may be made.

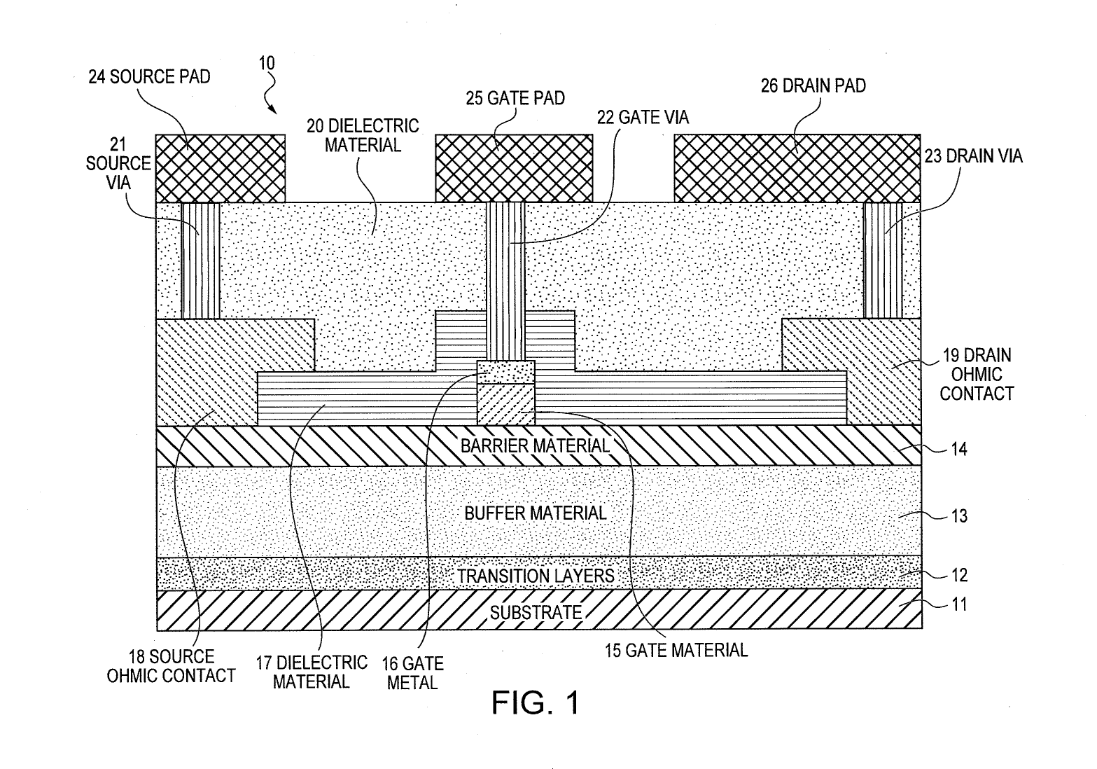

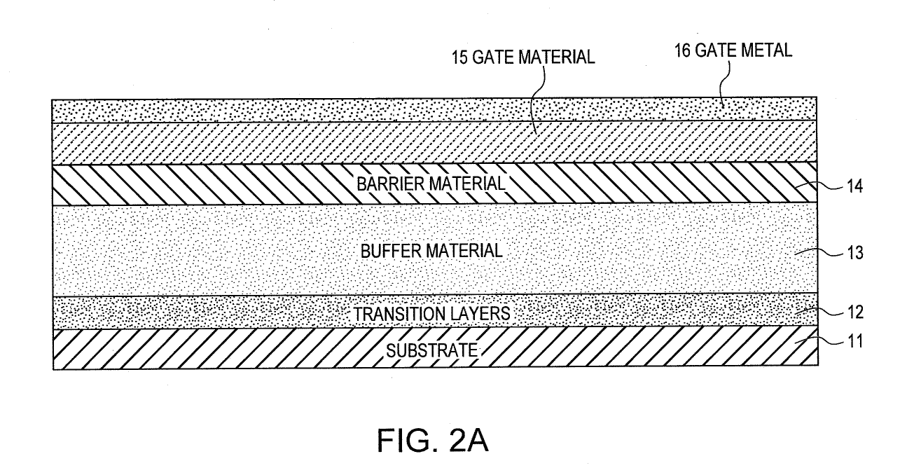

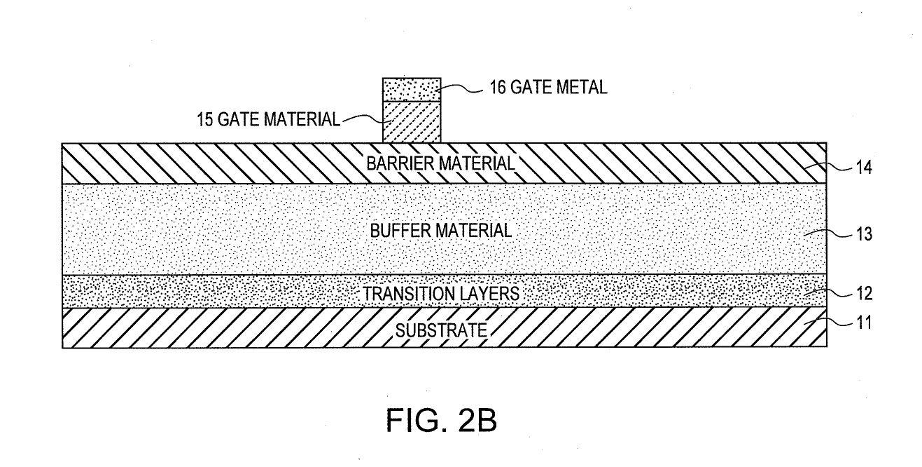

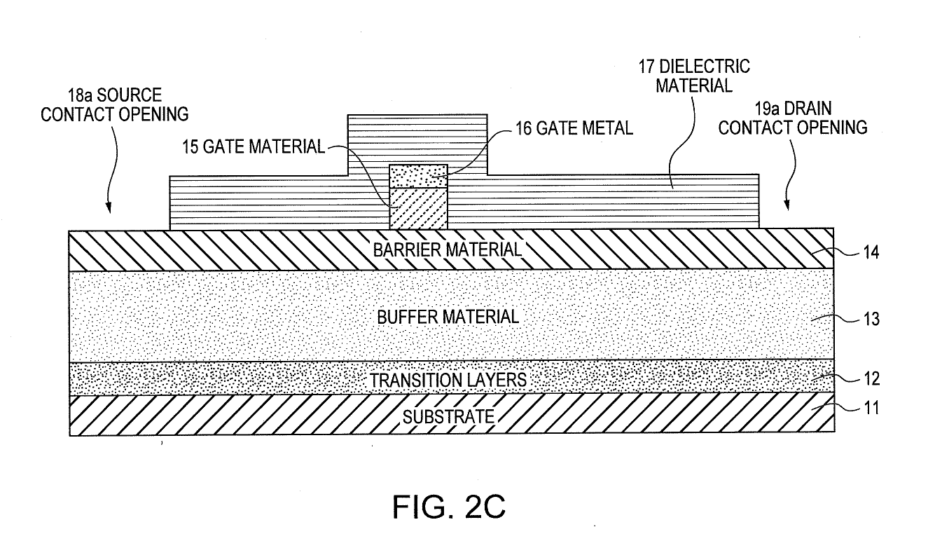

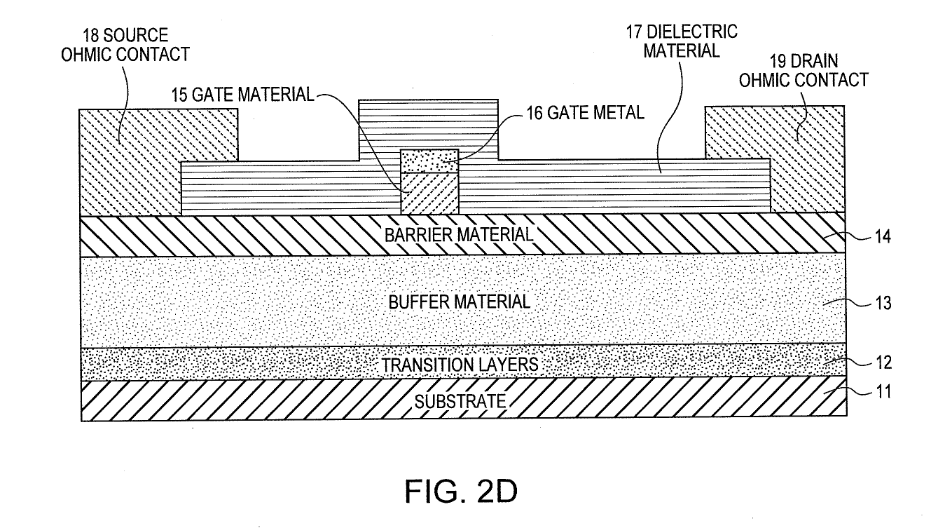

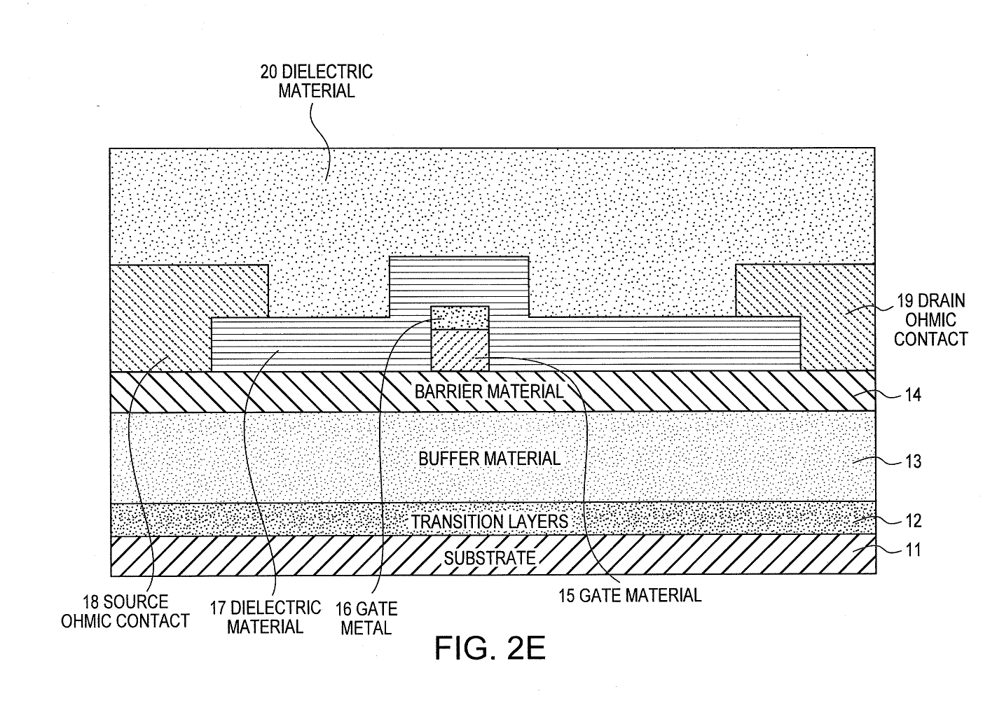

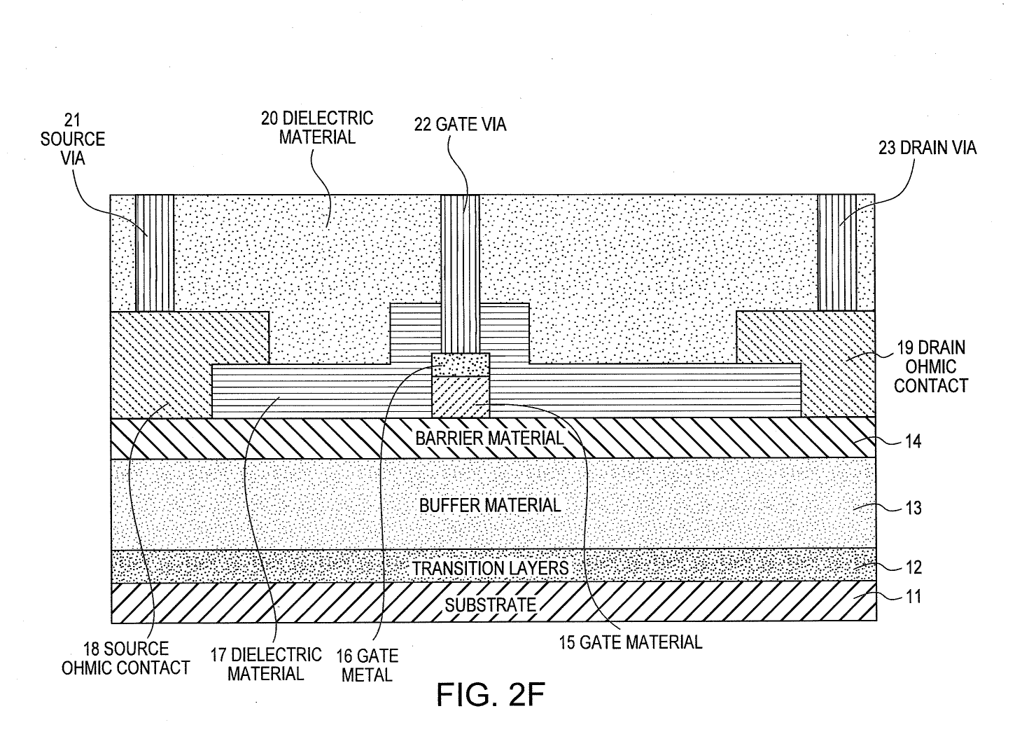

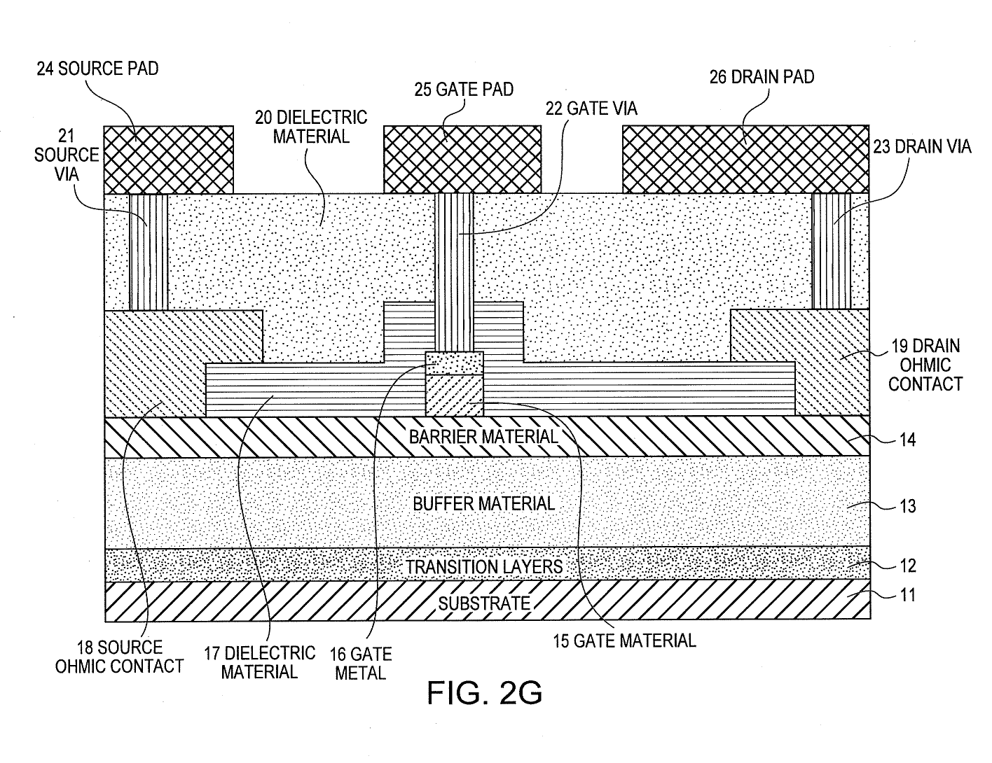

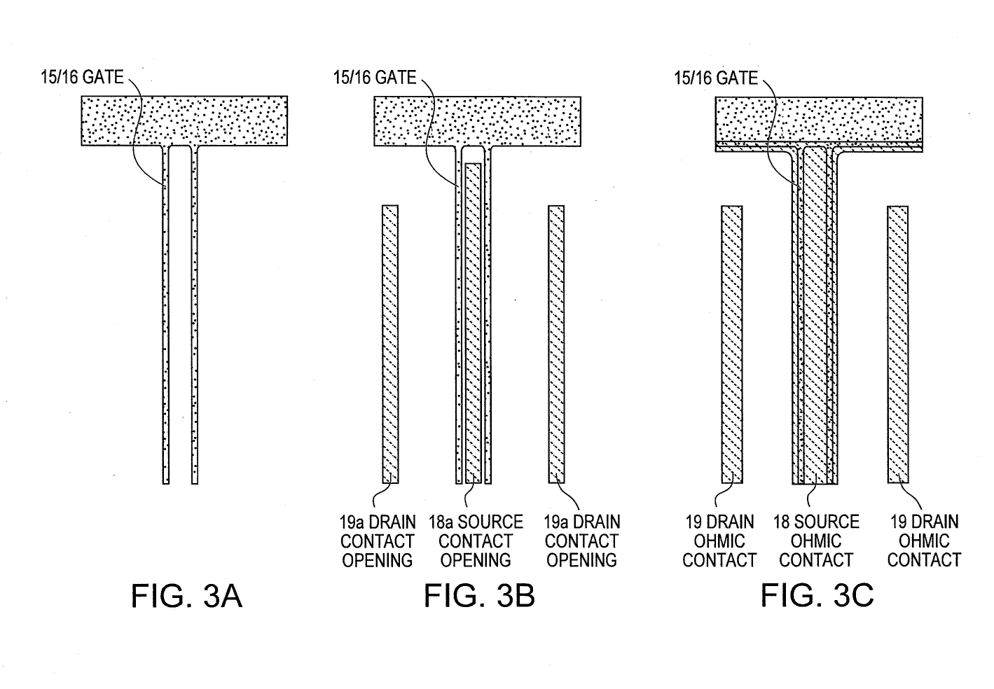

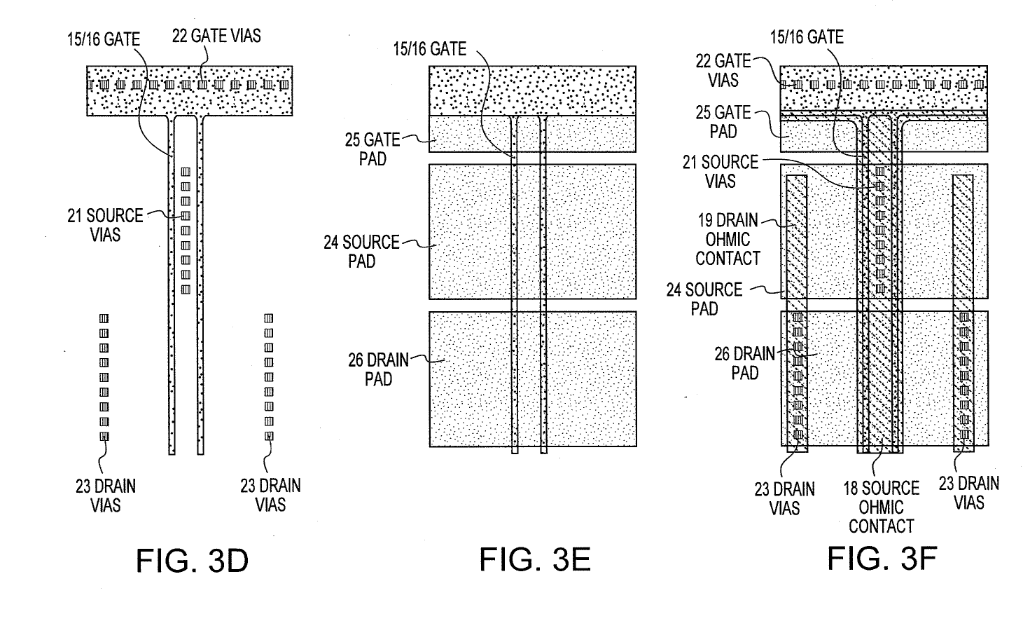

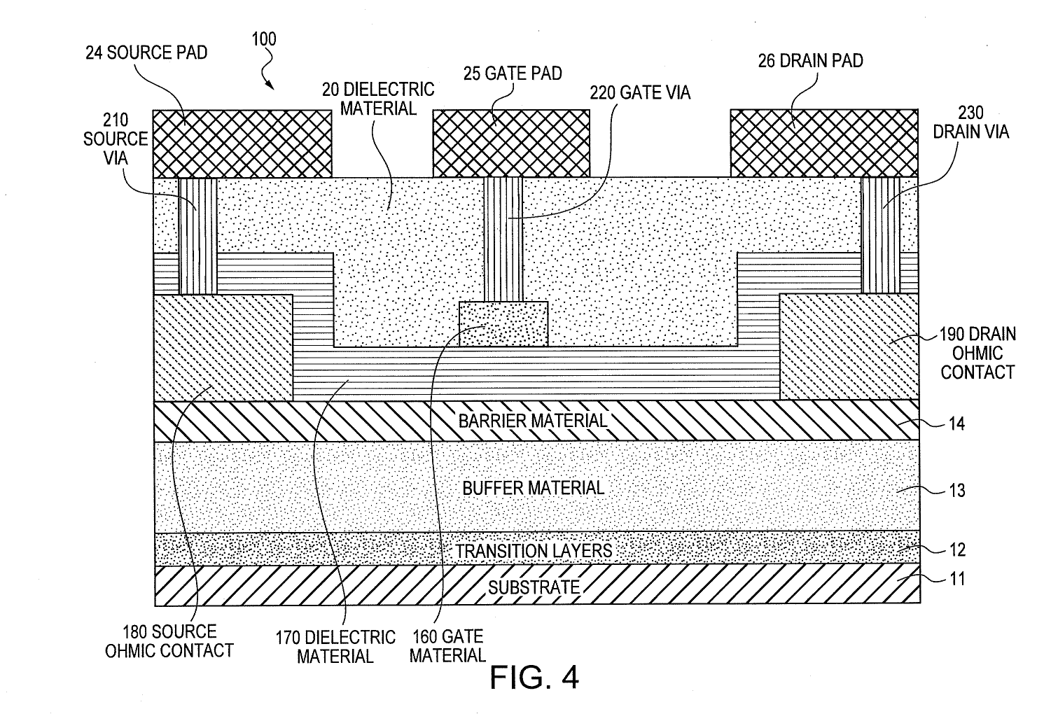

A first embodiment is described in relation to FIGS. 1, 2A-2G, and 3A-3F, wherein like reference numbers are used consistently for like features throughout the drawings, unless otherwise noted. FIG. 1 illustrates a semiconductor device 10, in this case, a GaN HEMT semiconductor device. Device 10 can be formed by the method described below with respect to FIGS. 2A-2G and FIGS. 3A-3F. Device 10 includes semiconductor materials typically used in forming a GaN semiconductor device, including a substrate 11, transition layers 12, an un-doped buffer material 13 (e.g., InAlGaN), an un-doped barrier material 14 (e.g., a layer of InAlGaN with a larger band gap than the buffer material). Semiconductor materials 11-14 may be epitaxial layers.

Device 10 also includes a gate formed of gate material 15 (e.g., a layer of InAlGaN) with p-type dopants and gate metal 16. Device 10 also includes upper-level contact pads corresponding to source, gate, and drain contacts, including an source pad 24 of upper level metal connecting to source Ohmic contact 18 through via 21, a gate pad 25 of upper level metal connecting to the gate through via 22, and a drain pad 26 of upper level metal connecting to drain Ohmic contact 19 through via 23. Source Ohmic contact 18 and drain Ohmic contact 19 may be formed of Ohmic contact metal made of titanium (Ti), aluminum (Al), or other suitable material, and may include a capping metal stack.

In device 10, a first dielectric material 17 and a second dielectric material 20 are located between gate pad 25 and the gate, and gate via 22 traverses first and second dielectric materials 17, 20. Second dielectric material 20 is also located between source pad 24 and source Ohmic contact 18, and between drain pad 26 and drain Ohmic contact 19. Source via 21 and drain via 22 traverse dielectric material 20.

FIGS. 2A-2G illustrate a process for forming a semiconductor device, such as semiconductor device 10 (FIG. 1). In FIG. 2A, an epitaxial structure of semiconductor materials 11-14 typically used in forming a GaN semiconductor device is provided. The semiconductor materials include, from bottom up, a substrate 11 (which may be made of silicon, or sapphire, or SiC, for example), transition layers 12, buffer material 13, barrier material 14. Barrier material 14 preferably has a thickness of about 50 Å to about 300 Å, and is composed of an un-doped InAlGaN material including Al that constitutes about 12 to 100 percent of the metallic content of the AlGaN material. Buffer material 13 preferably has a thickness in a range of about 0.05 to about 10 μm, and may be in a range of about 0.5 to about 5 μm. Buffer material 13 is preferably composed of an un-doped InAlGaN with an Al content lower than the Al content of barrier material 14. Transition layers 12 have a collective thickness that is preferably in a range of about 0.3 um to 2 um, and may contain one or more layers composed of AlN and AlGaN. Transition layers 12 may also include a superlattice structure.

Also provided in FIG. 2A are a layer of gate material 15 and a layer of gate metal 16. The layer of gate material 15 can be epitaxially grown over barrier material 14, or alternatively can be deposited on top of barrier material 14. The layer of gate metal 16 can be epitaxially grown over gate material 15, or alternatively can be deposited on top of gate material 15. Gate material 15 preferably has a thickness in the range of about 100 Å to about 2000 Å. Additionally, gate material 15 is preferably composed of a p-type GaN material having a doping concentration in the range of about 10¹⁸ to about 10²¹ atoms per cm³. Gate metal 16 can be made of a refractory metal or its compound, e.g., tantalum (Ta), tantalum nitride (TaN), titanium nitride (TiN), palladium (Pd), tungsten (W), tungsten silicide (WSi₂), and preferably has a thickness in the range of about 0.05 um to 1 um.

In FIG. 2B, gate metal 16 and gate material 15 are etched to form the gate. Gate metal 16 and gate material 15 may be etched by any known technique. For example, a gate photo mask (not shown) may be used to pattern and etch gate metal 16 and gate material 15. Plasma etching, followed by a photoresist strip, may also be used.

In FIG. 2C, a layer of a first dielectric material 17, such as silicon nitride (Si₃N₄), is deposited or formed on top of exposed portions of barrier layer 14 and the remaining gate metal 16. After deposition of first dielectric material 17, a contact photo mask may be used to pattern and etch portions of first dielectric material 17, and a photoresist strip then applied in order to form source contact opening 18a and drain contact opening 19a.

In FIG. 2D, Ohmic contact metal is deposited at source contact opening 18a and drain contact opening 19a to form source Ohmic contact 18 and drain Ohmic contact 19. The Ohmic contact metal can be composed of titanium (Ti), aluminum (Al), or other suitable material, and may include a capping metal stack. After Ohmic contact metal deposition, a metal mask is used to pattern and etch the Ohmic contact metal to form the desired dimensions of source Ohmic contact 18 and drain Ohmic contact 19. A rapid thermal anneal (RTA) process is performed to form Ohmic connections between source and drain Ohmic contacts 18, 19 and the conductive two dimensional electron gas (2DEG) region located beneath barrier layer 14. RTA processes known in the art are typically performed at temperatures in a range of about 800° C. to 900° C.

In FIG. 2E, a second dielectric material 20 is deposited over dielectric material 17 and Ohmic contacts 18, 19. Second dielectric material 20 can then be planarized in order to be suitable for forming upper level contacts (described in connection with FIG. 2G, below).

The step of depositing the second dielectric material 20 is now described in further detail. In some embodiments, this step may include use of plasma enhanced deposition, where a combination of reactive silicon containing gas and an oxygen containing gas are injected into a chamber containing the wafer under process. In a plasma enhanced deposition, a high energy electric field is applied within the chamber to excite or energize the gases, such that they can react with one another and form silicon dioxide (SiO₂) on the surface of the wafer. The use of an electric field to stimulate this reaction is called plasma enhancement.

A variety of gases may be used to supply the silicon and oxygen that participate in the formation of the SiO₂. These include Silane (SiH₄), tetraethylorthosilicate (TEOS), dichlorosilane (DCS), or other silicon containing gas, as well as an oxygen containing gas, such as nitrous oxide (NO₂) or oxygen (O₂). A variety of names are used for this type of deposition depending on the gases used. Plasma Enhanced Chemical Vapor Deposition (PECVD) is a general term for the approach to material deposition, and plasma enhanced oxide (PEOX) is generally used for silane base processing, while plasma enhanced tetraethylorthosilicate (PETEOS) is used to indicate that TEOS is used as the reactive silicon containing gas.

Spin on Glass (SOG) is an alternative approach to using PECVD based deposition. In a SOG process, a semi-stable material containing silicon and oxygen is coated onto the wafer and then exposed to high temperature. During the high temperature step, the semi-stable chemical breaks down into a silicon oxide, and a volatile gas that leaves the surface. A layer of silicon oxide remains after the chemical is fully decomposed. The advantage of this approach is that the SOG fills gaps and holes, leaving a smooth surface after the high temperature step. The draw back to this approach is that SOG deposited material is of very poor material and is not generally left on the wafer.

A combination of PECVD and SOG processes can be used to produce a smooth surface, but without leaving residual SOG material. This planarization approach has 3 steps. First a PECVD based film is deposited over the wafer. Second, a SOG layer is deposited over the PECVD film, which produces a smooth surface. Third, a uniform etch is applied to the surface, etching away all of the SOG, and some of the PECVD deposited film. This results in a smooth film of only the PECVD material remaining. Further deposition using PECVD may be employed to thicken this smooth film as necessary. A plasma enhancement deposition technique for depositing the second dielectric material 20 may include, for example, deposition of one or more materials from a group consisting of PEOX, PETEOS, and SOG, a plasma etch back process, and a re-deposition of PEOX.

Alternatively, this process step may include deposition of a very thick film of PECVD based material, such as PEOX and PETEOS, followed by a chemical mechanical polishing (CMP) process. CMP is very similar to sanding. A paste of very fine diamond grit, and a dilute etching chemical, is used to slowly polish away the high areas of the wafer surface. A very flat surface is used to polish the wafer against, such that the surface remains flat over the entire surface.

Other appropriate methods for depositing dielectric material that are known in the art may also be used for the step of depositing the second dielectric material 20.

Referring now to FIG. 2F, a via mask (not shown) is used to pattern and etch via 21 above source Ohmic contact 18, via 22 above the gate, and via 23 above drain Ohmic contact 19. Vias 21 and 23 traverse dielectric material 20. Via 22 traverses dielectric material 20 and dielectric material 17. Dielectric material 17 remains surrounding the sidewalls of the gate formed by gate metal 16 and gate material 15. After the via etch process is complete, the via mask is removed.

Referring now to FIG. 2G, vias 21, 22, 23 are filled with a conductive material, such as a Tungsten (W) plug or other suitable conductive material. An upper level metal is deposited over vias 21, 22, 23 and dielectric material 20, and a metal mask is used to pattern and etch the upper level metal, forming source pad 24, gate pad 25, and drain pad 26 above vias 21, 22, 23, respectively. The metal mask is then removed. The upper level metal of source, gate, and drain pads 24, 25, 26 may be formed using a hot aluminum process. In addition, the same material and process used to form the source, gate, and drain pads 24, 25, 26 (such as a hot aluminum process) may be used to fill vias 21, 22, 23.

For illustrative purposes, the cross-sectional views in FIG. 1 and FIGS. 2A-2G show vias 21, 22, 23 and pads 24, 25, and 26 in a single cross-sectional plane. These elements, however, may not be coplanar and may not be visible in a single cross-sectional view. FIGS. 3A-3F illustrate top views of various layers of conductive elements. FIG. 3A shows an example of a top view of the gate, which includes gate layer 15 covered by gate metal 16 (shown as coextensive in FIG. 3A). FIG. 3B shows the locations of source contact opening 18a and drain contact opening 19a (as described above with regard to FIG. 2C) relative to the gate. FIG. 3C shows the locations of source Ohmic contact 18 and drain Ohmic contact 19 (described above with regard to FIG. 2D) relative to the gate. FIG. 3D shows the locations of vias 21, 22, and 23 relative to the gate. FIG. 3E shows the locations of source, gate, and drain pads 24, 25, and 26 relative to the gate. FIG. 3F illustrates the relative locations of the gate, source Ohmic contact 18, drain Ohmic contact 19, vias 21, 22, 23, and pads 24, 25, and 26.

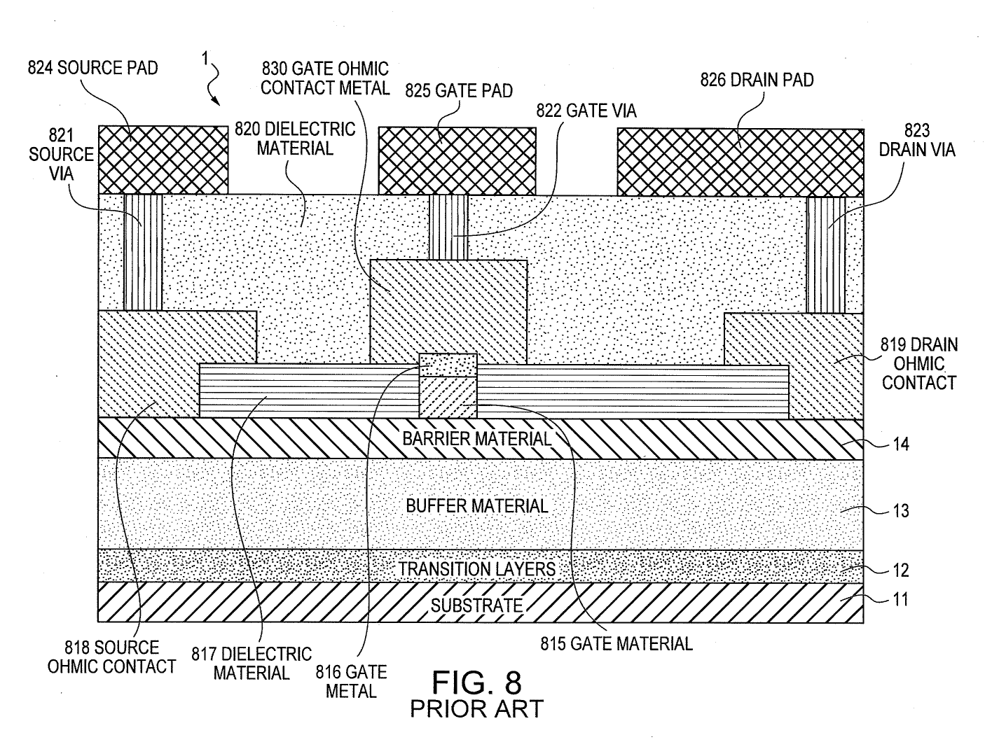

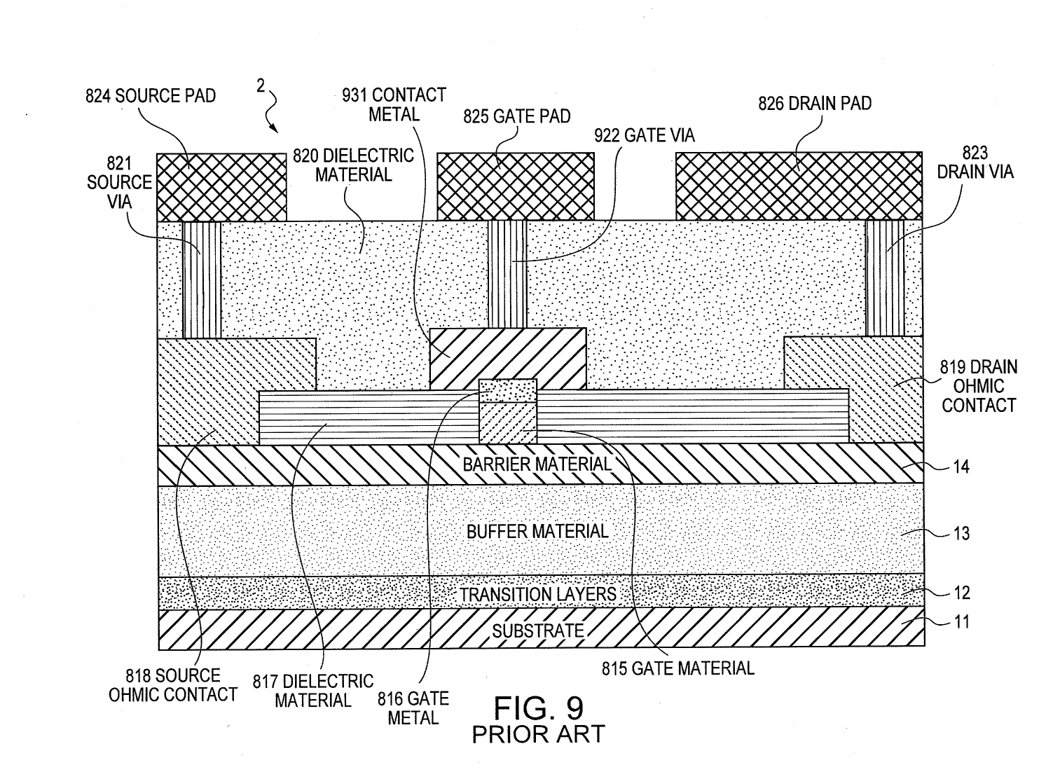

Unlike in the conventional via structures of semiconductor devices 1 and 2 (FIGS. 8 and 9, respectively), in device 10, the portion of dielectric material 17 over gate metal 16 is not removed prior to depositing Ohmic contact metal to form source and drain Ohmic contacts 818, 819, and a separate contact metal is not formed over the gate. Rather, gate via 22 traverses the dielectric material 17 and directly connects to the gate.

By way of contrast, in the GaN HEMT device 1 (FIG. 8), vias 721, 722, 723 traverse dielectric material 720, and none of vias 721, 722, 723 traverse dielectric material 717 (which may be removed) or Ohmic contact metal 730. Device 10 of FIG. 1, on the other hand, includes dielectric material 17 above gate metal 16, and does not include Ohmic contact metal in contact with the gate. The manufacturing process for device 10 includes the same number of processing steps as the manufacturing process for device 1, but reduces or eliminates gate degradation during the RTA process.

In GaN HEMT device 2 (FIG. 9), vias 821, 922, 823 traverse dielectric material 820, and none of the vias 821, 922, 823 traverse dielectric material 817 (which may be removed). Device 10 of FIG. 1, on the other hand, includes dielectric material 17 above the gate metal 16, and does not include a gate contact formed from another type of metal. Unlike device 2, device 10 does not require additional materials or processing steps during fabrication.

FIG. 4 illustrates a cross-sectional view of a semiconductor device 100 according to a second embodiment. Device 100 is a GaN HFET semiconductor device. Similar to device 10 (FIG. 1), device 100 includes semiconductor materials typically used in forming a GaN semiconductor device, including a substrate 11, transition layers 12, buffer material 13, and barrier material 14. Device 100 also includes gate material 160, source Ohmic contact 180, and drain Ohmic contact 190. Device 100 also includes dielectric material 20, on the planarized surface of which is formed source pad 24, gate pad 25, and drain pad 26.

Device 100 includes a dielectric material 170 having a similar composition and properties to dielectric material 17 (described above with regard to FIG. 1). Similarly, dielectric material 170 may be epitaxially formed or deposited above barrier material 14. In device 100, however, dielectric material 170 is formed over source and drain Ohmic contacts 180, 190, and gate material 160 is formed over dielectric material 170.

In device 100, between source pad 24 and source Ohmic contact 180, and between drain pad 26 and drain Ohmic contact 190, is dielectric material 20 and dielectric material 170. Between gate pad 25 and gate material 160 is dielectric material 20. While the semiconductor device 10 shown in FIG. 1 includes dielectric material 17 formed over gate material 16, semiconductor device 100 shown in FIG. 4 includes gate material 160 located above dielectric material 170. Also, source and drain Ohmic contacts 180, 190 of FIG. 4 are covered by dielectric material 170, and source via 210 and drain via 230 traverse dielectric material 170 and directly connect to source Ohmic contact 180 and drain Ohmic contact 190, respectively.

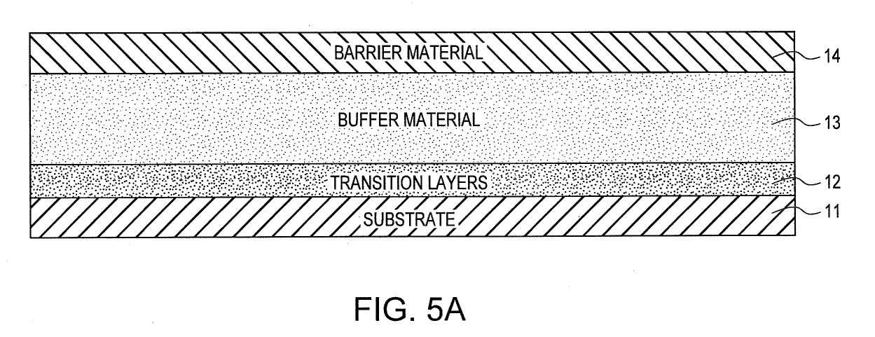

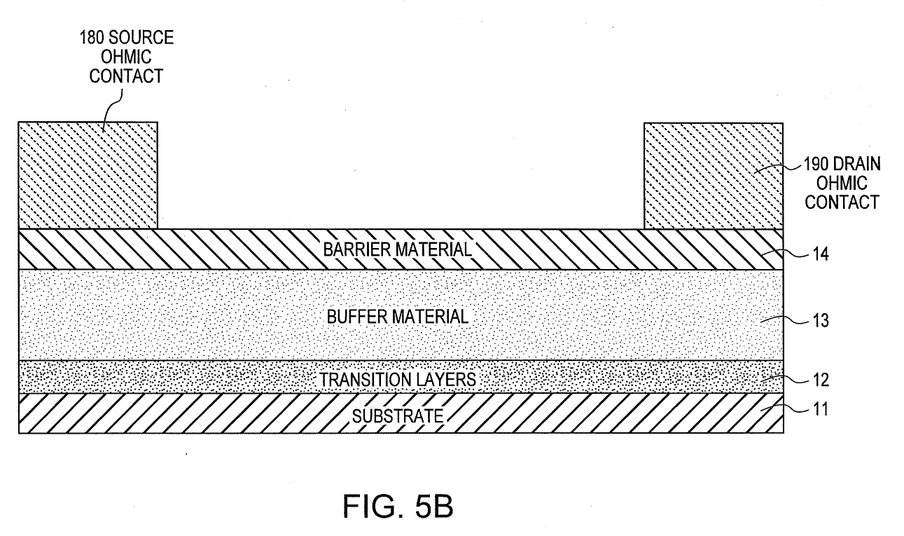

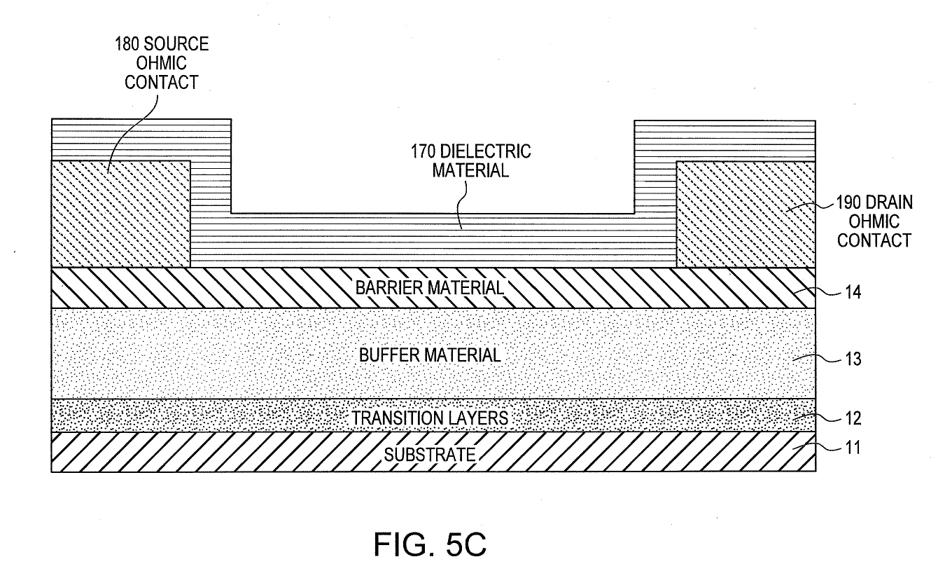

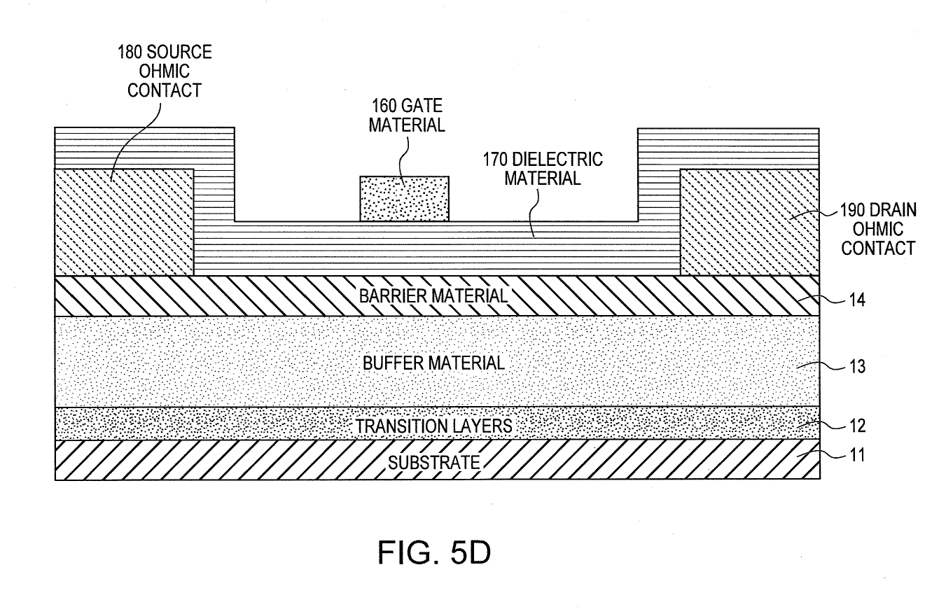

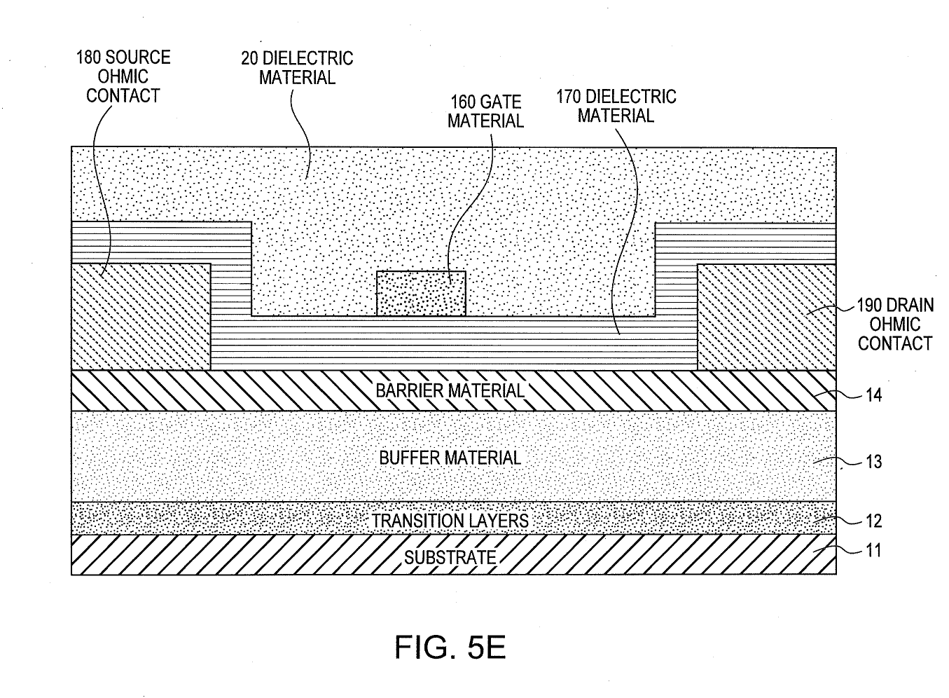

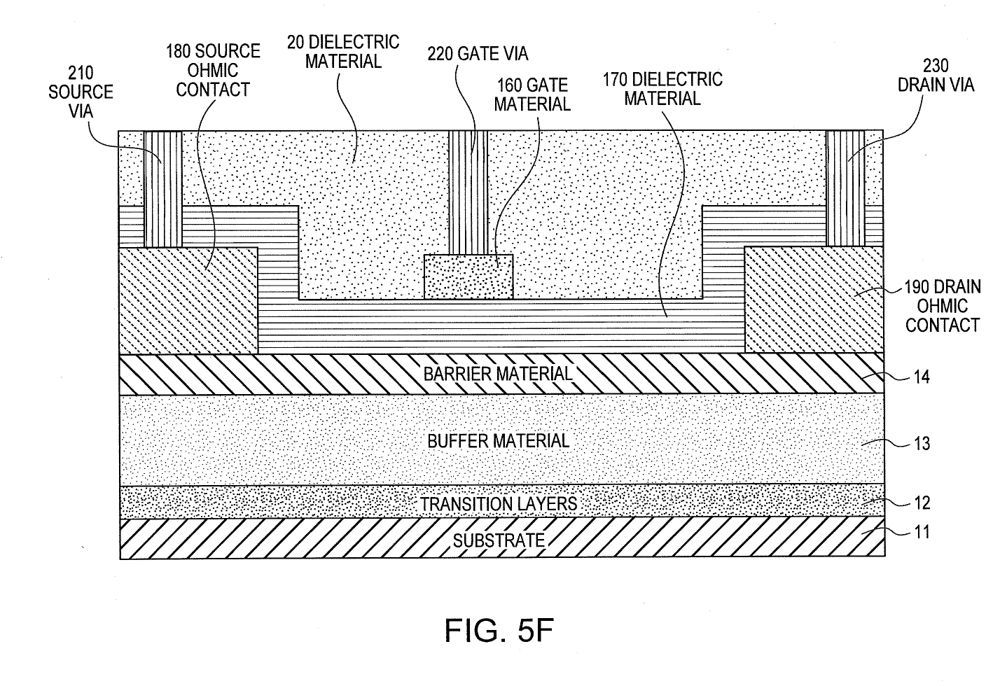

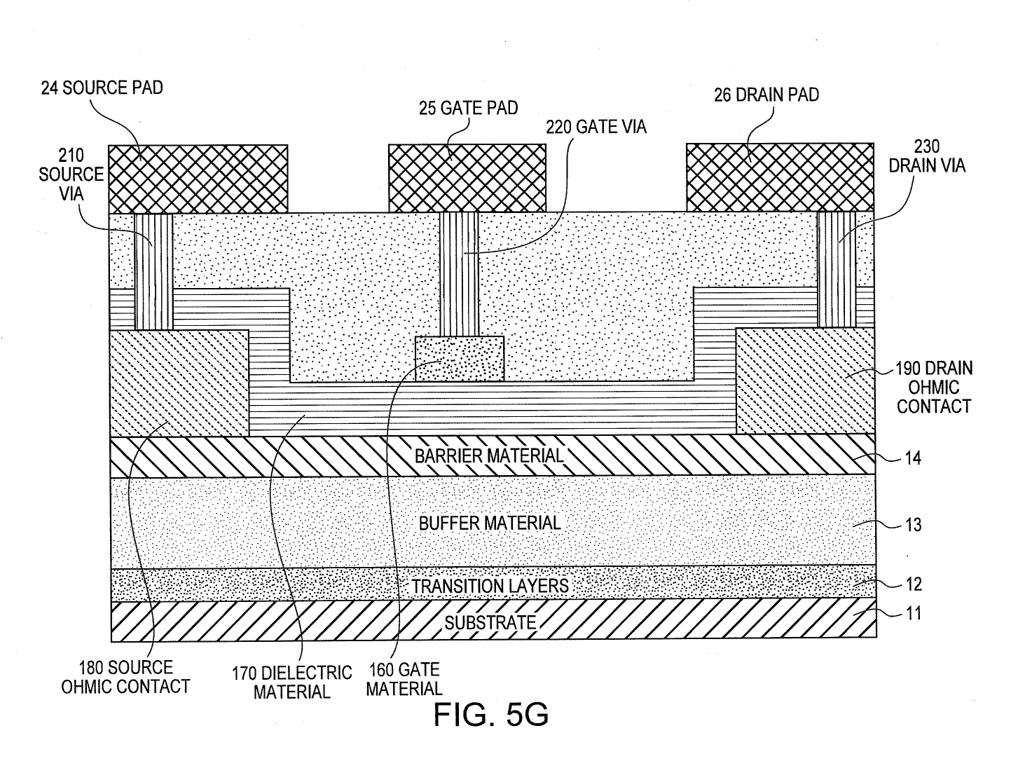

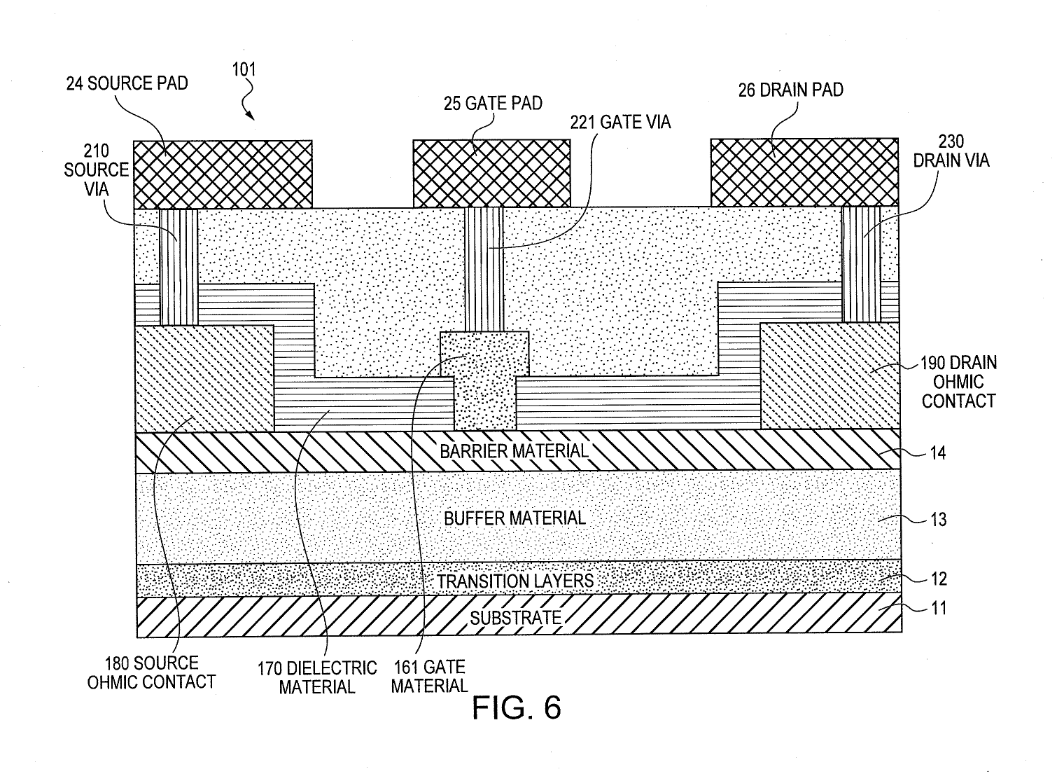

FIGS. 5A-5G illustrate a process for forming a semiconductor device, such as semiconductor device 100 (FIG. 4). In FIG. 5A, an epitaxial structure of semiconductor materials 11-14 typically used in forming a GaN semiconductor device is provided. The semiconductor materials include, from bottom up, a substrate 11 (which may be made of silicon, or sapphire, or SiC, for example), transition layers 12, buffer material 13, barrier material 14.

In FIG. 5B, respective source and drain Ohmic contacts 180, 190 are formed on barrier material 14. Source and drain Ohmic contacts 180, 190 may be formed in similar manner as described above with regard to FIG. 2D.

In FIG. 5C, a first dielectric material 170 (which may include properties similar to those of dielectric material 17 described above with regard to FIG. 2C) is formed over the exposed portion of barrier material 14 and source and drain Ohmic contacts 180, 190. Dielectric material 170 may be formed epitaxially, or may be deposited.

In FIG. 5D, a gate is formed of gate material 160. The gate may be formed through a mask and etching process similar to that described above with regard to FIG. 2B, or through other appropriate processes known in the art.

In FIG. 5E, a second dielectric material 20 is formed over gate material 160 and first dielectric material 170. Dielectric material 20 may be formed in similar manner to dielectric material 20 discussed above with regard to FIG. 2E.

In FIG. 5F, respective source, gate, and drain vias 210, 220, 230 are formed over source Ohmic contact 180, gate material 160, and drain Ohmic contact 190. Vias 210, 220, 230 may be formed using a via mask or through other known techniques. Source via 210 and drain via 230 are formed to traverse both the first dielectric material 170 and the second dielectric material 20. Gate via 220 is formed to traverse dielectric material 20 to gate material 160.

In FIG. 5G, vias 210, 220, 230 are filled with a conductive material (such as a Tungsten (W) plug), and upper level metal is formed into source pad 24, gate pad 25, and drain pad 26 over vias 210, 220, 230, respectively.

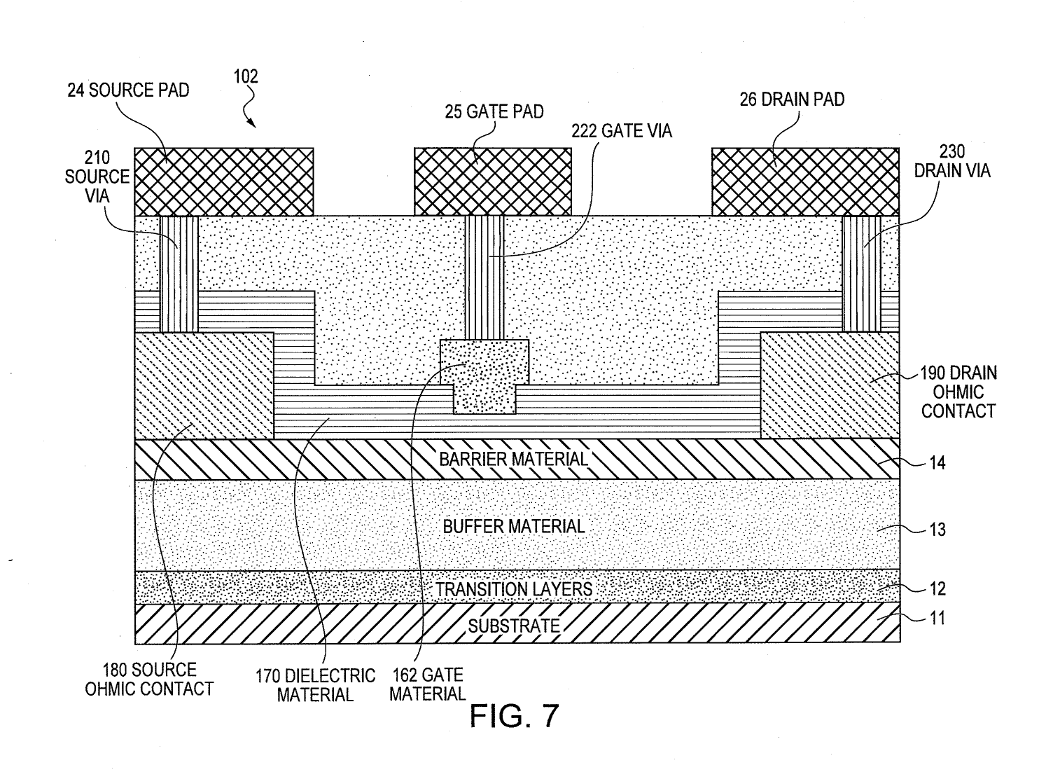

FIG. 6 illustrates a cross-sectional view of a semiconductor device 101 according to another embodiment. Device 101 is a GaN HFET semiconductor device including similar features to device 100 (FIG. 4), and like reference numbers indicate like features. In device 101, however, gate material 161 traverses dielectric material 170, and is in direct contact with barrier material 140. Device 101 may be used to form a Schottky gate contact.

FIG. 7 illustrates a cross-sectional view of a semiconductor device 102 according to another embodiment. Device 102 is a GaN HFET device including similar to device 101 (FIG. 6), and like reference numbers indicate like features. In device 102, however, gate material 162 only extends partially into dielectric material 170 and is not in direct contact with barrier material 140. A dielectric material 172 (which may be a portion of dielectric material 170) is located underneath gate material 162 between gate material 162 and barrier material 140.

The above description and drawings are only to be considered illustrative of specific embodiments, which achieve the features and advantages described herein. Modifications and substitutions to specific process conditions can be made. Accordingly, the embodiments of the invention are not considered as being limited by the foregoing description and drawings.

What is claimed as new and desired to be protected by Letters Patent of the United States includes the following:

1. A semiconductor device comprising:
semiconductor materials located on a substrate, said semiconductor materials having a surface;
a first contact located above a portion of said surface of said semiconductor materials, said first contact for applying an electrical signal to said semiconductor materials;
a first dielectric material formed directly over said first contact and at least a portion of said surface of said semiconductor materials;
a second dielectric material formed above said first dielectric material and said first contact;
a first pad electrically connected to said first contact formed on said second dielectric material; and
a first via electrically connecting said first contact to said first pad, wherein said first via traverses said first dielectric material and said second dielectric material.

2. The semiconductor device of claim 1, wherein said first via is directly connected to said first contact.

3. The semiconductor device of claim 1, wherein said first contact is a gate of said semiconductor device.

4. The semiconductor device of claim 3, said gate further comprising:
a gate material composed substantially of a p-type GaN material, wherein said gate material is formed directly on said surface of said semiconductor materials; and
a gate metal composed substantially of a refractory metal or its compound formed over said gate material, wherein said first via is directly connected to said gate metal.

5. The semiconductor device of claim 3, further comprising:
at least one Ohmic contact formed on said surface of said semiconductor device, wherein said at least one Ohmic contact is not covered by said first dielectric material;
a second pad electrically connected to said at least one Ohmic contact; and
a second via electrically connecting said at least one Ohmic contact to said second pad, wherein said second via traverses said second dielectric material.

6. The semiconductor device of claim 1, wherein said first contact is one of a source or drain Ohmic contact of said semiconductor device.

7. The semiconductor device of claim 6, further comprising:
a gate formed on said first dielectric material;
a second pad for receiving an electrical signal from an external source for said gate; and
a second via electrically connecting said gate to said second pad, wherein said second via traverses said second dielectric material.

8. The semiconductor device of claim 7, wherein said gate partially traverses said first dielectric material.

9. The semiconductor device of claim 7, wherein said gate completely traverses said first dielectric material.

10. The semiconductor device of claim 7, said gate comprising a gate metal composed substantially of a refractory metal or its compound.

11. The semiconductor device of claim 1, wherein said first dielectric material is composed substantially of silicon nitride.

12. The semiconductor device of claim 1, wherein said semiconductor device is a gallium-nitride (GaN) semiconductor device, said semiconductor materials comprising:
at least one transition layer formed on said substrate;
a buffer material formed on said at least one transition layer; and
a barrier material formed on said buffer material,
wherein said first contact is formed on a surface of said barrier material.

13. A method of forming a semiconductor device, said method comprising:
providing semiconductor materials on a substrate, said semiconductor materials having a surface;
forming a first contact on a portion of said surface of said semiconductor materials;
forming a first dielectric material on another portion of said surface of said semiconductor materials and on said first contact;
forming a second dielectric material over said first dielectric material;
forming a first via that traverses said first and second dielectric materials and directly connects to said first contact; and
forming a first pad on said second dielectric material, wherein said first pad is electrically connected to said first contact.

14. The method of claim 13, wherein said first contact is a gate, said step of forming a first contact comprising etching a layer of gate material formed on said surface of said semiconductor materials and a layer of gate metal on said layer of gate material to form said gate.

15. The method of claim 14, said step forming a first dielectric material further comprising:
forming a layer of said first dielectric material on an exposed portion of said semiconductor materials and on said gate; and
removing portions of said layer of said first dielectric material to provide respective openings for source and drain Ohmic contacts of said semiconductor device.

16. The method of claim 15, further comprising, prior to forming said second dielectric material, forming said source and drain Ohmic contacts on said surface of said semiconductor materials in said respective openings.

17. The method of claim 16, further comprising performing a rapid thermal anneal process to establish Ohmic contact between a 2DEG region of said semiconductor materials and source and drain Ohmic contacts.

18. The method of claim 17, wherein said step of forming a first via further comprises forming second and third, vias that traverse said second dielectric material and directly connect to a respective one of said source and drain Ohmic contacts.

19. The method of claim 13, wherein said first contact is at least one source or drain Ohmic contact, said step of forming a first contact comprising:
forming said at least one source or drain Ohmic contact on a portion of said surface of said semiconductor materials; and
performing a rapid thermal anneal process to establish Ohmic contact between a 2DEG region of said semiconductor materials and said at least one source or drain Ohmic contact.

20. The method of claim 19, wherein said step of forming said first dielectric material comprises forming a layer of said first dielectric material over an exposed portion of said surface of said semiconductor materials and over said at least one source or drain Ohmic contact.

21. The method of claim 20, further comprising forming a gate on said first dielectric material prior to forming said second dielectric material.

22. The method of claim 21, wherein said step of forming a first via further comprises forming at least a second via traversing said second dielectric material and directly connected to said gate.

23. The method of claim 13, wherein said step of providing semiconductor materials on a substrate comprises providing an epitaxial structure including:
at least one transition layer formed on said substrate;
a layer of buffer material formed on said at least one transition layer; and
a layer of barrier material formed on said buffer material,
wherein said surface of said semiconductor materials is a surface of said layer of barrier material.

24. The method of claim 14, wherein said step of providing semiconductor materials on a substrate comprises providing an epitaxial structure including:
at least one transition layer formed on said substrate;
a layer of buffer material formed on said at least one transition layer;
a layer of barrier material formed on said buffer material, wherein said surface of said semiconductor materials is a surface of said layer of barrier material;
said layer of gate material formed on said surface of said layer of barrier material; and
said layer of gate metal formed on said layer of gate material.

25. The method of claim 13, wherein said step of forming a first via further comprises:
using a via mask to pattern and etch said first via above said at least one contact; and
filling said first via with a conductive material.
